(19) United States
(12) Patent Application Publication
(10) Pub. No.: US 2015/0223345 A1
(43) Pub. Date: Aug. 6, 2015

(54) METHOD OF FORMING WIRING PATTERN, AND WIRING PATTERN FORMATION

(71) Applicant: Toray Industries, Inc., Tokyo (JP)

(72) Inventors: Hirokazu Ninomiya, Otsu (JP); Kiyohiko Ito, Otsu (JP); Yusuke Kawabata, Otsu (JP)

(21) Appl. No.: 14/425,992

(22) PCT Filed: Aug. 29, 2013
(86) PCT No.: PCT/JP2013/073136

§ 371 Date: Mar. 4, 2015

(30) Foreign Application Priority Data
Sep. 25, 2012 (JP) 2012-210687

(51) Int. Cl. H05K 3/02; H05K 3/00; H05K 1/11

(52) U.S. Cl. CPC H05K 3/027; H05K 1/11; H05K 3/0079

(57) ABSTRACT

A wiring pattern forming method includes a first, second, and third step performed in sequence, the first step including depositing a resist layer on the non-wiring section of the first surface of an insulating substrate, the second step including depositing an electroconductive thin film layer on the wiring section and at least part of the resist layer, and the third step including radiating flash light in the visible band from a flash lamp onto at least the second surface of the resist layer via the second surface of the insulating substrate and dissolving the resist layer to form a wiring pattern made of the electroconductive thin film layer in the wiring section.

### TECHNICAL FIELD

This disclosure relates to a wiring pattern forming method, in particular a wiring pattern forming method useful to produce a wiring board based on a difficult-to-etch noble metal or a printed wiring board, as well as a formed wiring pattern.

### BACKGROUND

Conventionally, metal wiring substrates produced by forming metal pattern-based wiring on the surface of an insulated substrate are widely used in electronic parts and semiconductor devices. Conventionally available wiring pattern forming methods include, for instance, the subtractive method, semi-additive method, full-additive method, and lift-off method (Japanese Unexamined Patent Publication (Kokai) No. 2004-063575, Japanese Unexamined Patent Publication (Kokai) No. 2004-172236, Japanese Unexamined Patent Publication (Kokai) No. 2005-136339, Japanese Unexamined Patent Publication (Kokai) No. 2009-176770, Japanese Unexamined Patent Publication (Kokai) No. HEI-8-274448, and Japanese Unexamined Patent Publication (Kokai) No. 2000-286536).

The subtractive method uses a laminate produced by forming a photoresist layer on a metal foil formed on an insulated substrate. A wiring pattern is obtained by placing a mask having the same shape as the desired conductor pattern on the resist layer of the laminate and exposing the resist layer to ultraviolet rays and developing it to remove it, except for the part that has been covered by the mask, followed by the removal of the conductor layer using an etching liquid, except for the part constituting the conductor pattern, which has been covered by the remaining part of the resist layer, and peeling of this same part of the resist layer (Japanese Unexamined Patent Publication (Kokai) No. 2004-063575, Japanese Unexamined Patent Publication (Kokai) No. 2004-172236, and Japanese Unexamined Patent Publication (Kokai) No. 2005-136339).

The semi-additive method, on the other hand, uses the following steps: a thin metal bed layer, some 0.3 to 3 μm in thickness, is formed on an insulating resin by non-electrolytic plating; after a photoresist layer is formed on the metal bed layer, it is irradiated with ultraviolet rays through a masking plate featuring a pattern that is a reverse of the desired circuit pattern; this exposes the part of the metal bed layer that forms the wiring circuit, while forming a resist pattern covered with photoresist film on the part of the metal bed layer that does not form the wiring circuit. An electric current is applied to the metal bed layer via a masking pattern formed on a power supply layer in the shape of the photoresist pattern to form a wiring circuit by electrolytic plating. A wiring pattern is then formed by removing the photoresist pattern and etching away the metal bed layer (Japanese Unexamined Patent Publication (Kokai) No. 2009-176770).

The so-called “lift-off” method is also known as a method to obtain a wiring pattern when an electroconductive circuit is to be formed on an insulated substrate using a noble metal such as Pt, Au or Pd, an alloy thereof or any other metal that is difficult to etch. In that case, a resist film is formed in advance in the shape that is a reverse of the desired circuit pattern, followed by formation of the metal layer using the vacuum vapor deposition method or sputtering method and the solvent-removal of the resist film (Japanese Unexamined Patent Publication (Kokai) No. HEI-8-274448 and Japanese Unexamined Patent Publication (Kokai) No. 2000-286536).

Meanwhile, a blood glucose sensor measures the blood glucose concentration by oxidizing an electron mediator through a reaction between the glucose component of the blood and enzymes such as GOD (glucose oxidase) and GDH (glucose dehydrogenase) and reading the electric current generated by it. However, electrodes used in such an electrochemical biosensor, including the active and return poles, are subject to a constraint such that they must be made of an electroconductive material that is not oxidized when the electron mediator is oxidized. For this reason, the electroconductive material must be chosen from palladium, gold, platinum, carbon, and the like. As a method to employ when using palladium, gold, platinum or some other noble metal, laser trimming has been disclosed (International Publication WO 2002/008743).

Those wiring pattern forming methods either involve tedious steps such as the use of an etching liquid, resist peeling liquid and other chemical substances or require the introduction of expensive machines such as laser irradiation equipment, and this gives rise to a need for a more effective method in terms of environmental and economic performance.

It could therefore be helpful to provide a new wiring pattern forming method and formed wiring pattern effective in terms of environmental and economic performance.

### SUMMARY

We thus provide a wiring pattern forming method characterized in that a first, second, and third step are performed in sequence, wherein the first step is a step of depositing a resist layer on the non-wiring section of the first surface of an insulating substrate, the second step is a step of depositing an electroconductive thin film layer on the wiring section and at least part of the resist layer, and the third step is a step of radiating flash light in the visible band from a flash lamp onto at least the second surface of the resist layer via the second surface of the insulating substrate and dissolving the resist layer to form a wiring pattern made of the electroconductive thin film layer in the wiring section.

Preferred examples of such a wiring pattern forming method are as specified in (1) to (11) below.
(1) The total light transmittance of the insulating substrate is 20% or more.
(2) The resist layer contains carbon.
(3) The resist layer contains an organic solvent.
(4) The boiling point of the organic solvent is 200° C. or less.
(5) The resist layer is formed using a method that includes at least one selected from a group of methods comprising gravure printing, flexographic printing, screen printing, offset printing, ink jet printing and photolithography.
(6) After the resist layer is formed, such a part thereof as to cover the wiring section is removed using the laser ablation method.
(7) The electroconductive thin film layer is made of an electroconductive material that is not carbon-based.
(8) The thickness of the electroconductive thin film layer is 1 nm to 20 μm.
(9) The electroconductive thin film layer is deposited using the sputtering method and/or vapor deposition method.
(10) The irradiation of flash light in the visible band causes at least part of the resist layer to evaporate.
(11) The irradiation energy of flash light in the visible band is 0.1 to 100 J/cm².

We also provide a wiring pattern formed through the use of the above wiring pattern forming method and a biosensor chip incorporating such a wiring pattern.

We make it possible to provide a new wiring pattern forming method and formed wiring pattern effective in terms of environmental and economic performance.

### BRIEF DESCRIPTION OF THE DRAWINGS

FIG. 1 is a cross-sectional diagram showing the first step of the wiring pattern forming method.

FIG. 2 is a cross-sectional diagram showing the second step of the wiring pattern forming method.

FIG. 3 is a cross-sectional diagram showing the third step of the wiring pattern forming method.

FIG. 4 is a cross-sectional diagram showing the wiring circuit obtained through the wiring pattern forming method.

FIG. 5 is a cross-sectional diagram showing the first step of the wiring pattern forming method.

FIG. 6 is a cross-sectional diagram showing the wiring circuit obtained through the wiring pattern forming method.

FIG. 7 is a schematic diagram showing the step to remove such a part of the resist layer as to cover the non-wiring section using the laser ablation method as part of the first step of the wiring pattern forming method.

FIG. 8 is a diagram showing an example of the spectrum of flash light.

FIG. 9 is a diagram showing an example of a negative wiring pattern.

FIG. 10 is a diagram showing an example of a biosensor produced from a wiring pattern formed by our methods.

FIG. 11 is a diagram showing an example of a negative wiring pattern.

FIG. 12 is a diagram showing an example of an RFID chip produced from a wiring pattern formed by our methods.

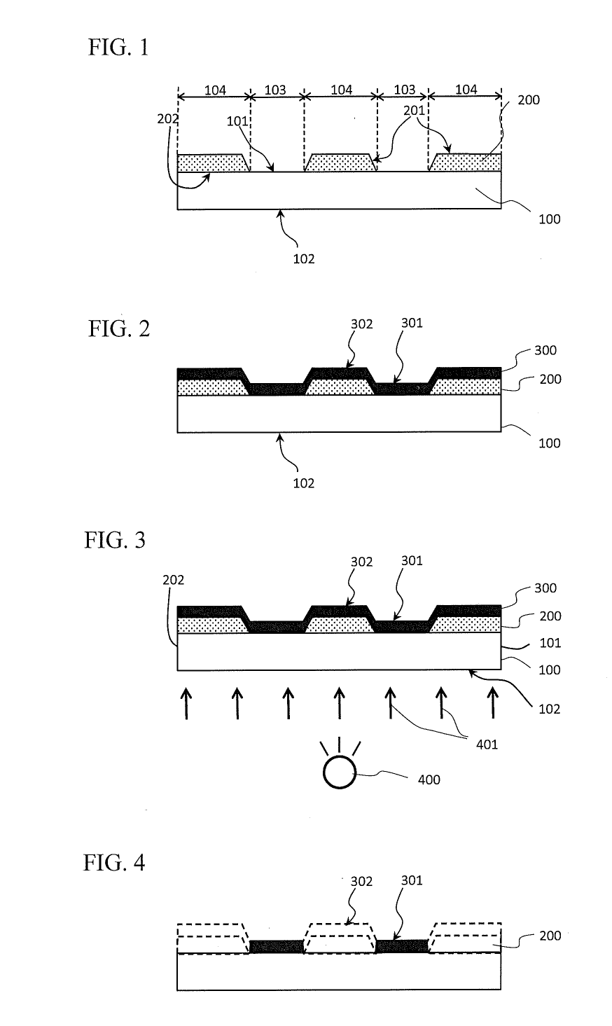

### EXPLANATION OF NUMERALS

100 Insulating substrate
101 First surface of insulating substrate
102 Second surface of insulating substrate
103 Wiring section
104 Non-wiring section
105 Laminated insulating substrate
106 First substrate constituting part of laminated insulating substrate
107 Second substrate also constituting part of laminated insulating substrate
107a PET film substrate
107b Adhesive layer
200 Resist layer
201 First surface of resist layer
202 Second surface of resist layer
300 Electroconductive thin film layer
301 Part of electroconductive thin film layer to become wiring pattern
302 Part of electroconductive thin film layer to be removed
400 Flash lamp
401 Flash light in visible band
500 Laser emission device
501 Laser beam
600 Enzyme battery
601 Active pole
602 Return pole
603, 604 Electrode
605 Electronic mediator layer
606 Enzyme layer
700 RFID tag
701, 702 Terminal
703 Strap
800 Wiring pattern

### DETAILED DESCRIPTION

As shown in the Drawings, the wiring pattern forming method is characterized in that the first step is a step of depositing a resist layer (200) on the non-wiring section (104) of the first surface of an insulating substrate, the second step is a step of depositing an electroconductive thin film layer (300) on the wiring section (103) and at least part of the resist layer (200), and the third step is a step of radiating flash light in the visible band (401) from a flash lamp (400) onto at least the second surface (202) of the resist layer (200) via the second surface (102) of the insulating substrate and dissolving the resist layer (200) to form a wiring pattern made of the electroconductive thin film layer (300) in the wiring section (103).

It is preferable that the insulating substrate (100) be transparent. For the purpose of this Description, an insulating substrate is deemed to be transparent if it more or less allows flash light in the visible band (401) incident on the second surface (102) of the insulating substrate to reach the first surface (101) and dissolve at least part of the resist layer (200). In concrete terms, it is preferable that the total light transmittance of the insulating substrate (100) as measured in accordance with JIS K7375 (2008) be 20% or more, more preferably 30% or more to allow the flash light in the visible band (401) to efficiently reach the resist layer (200) without attenuating and dissolve at least part of the resist layer (200). If the total light transmittance of the insulating substrate (100) is less than 20%, it is difficult for the flash light in the visible band (401) to efficiently reach the resist layer (200) due to attenuation, sometimes leading to a failure to dissolve the resist layer (200). There are no specific limitations on the upper limit to the total light transmittance of the insulating substrate (100), and there is no particular problem with values infinitely close to 100%.

The insulating substrate (100) is made of, for instance, a glass or plastic film. As the concrete material for the glass or plastic film, any generally known material may be used to the extent that it does not impair the characteristics of the product. Examples of a plastic film include polyester, polyolefin, polyamide, polyester amide, polyether, polyimide, polyamide-imide, polystyrene, polycarbonate, poly-p-phenylene sulfide, polyether ester, polyvinyl chloride, polyvinyl alcohol, poly(meta-)acrylate, and an acetate-based, polylactic acid-based, fluorine-based or silicone-based plastic material. Copolymers, blends or crosslinked compounds thereof may also be used.

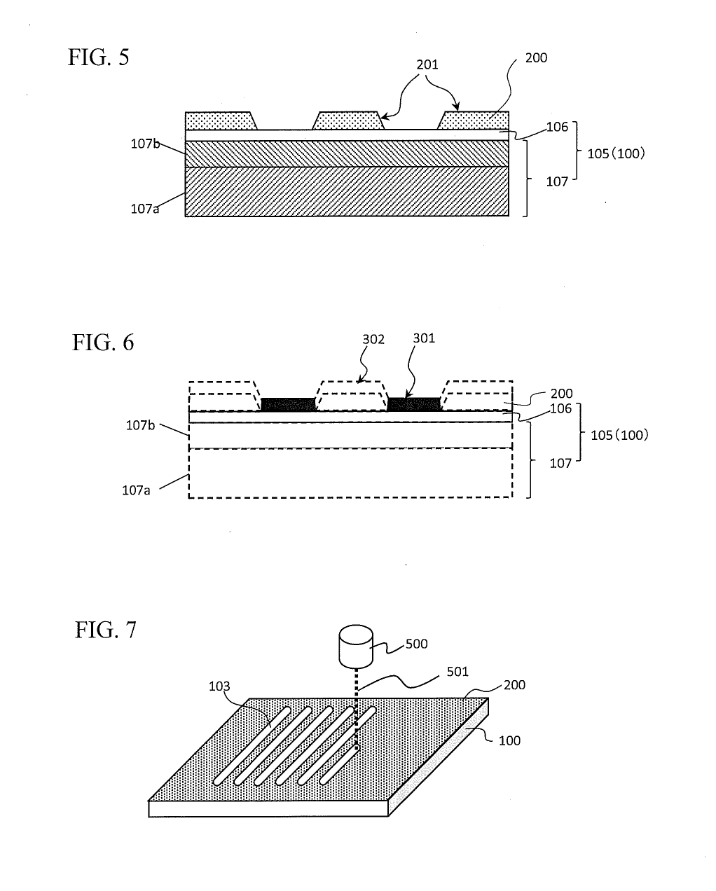

As long as the total light transmittance range specified above can be maintained, a laminate of two or more films is also acceptable. With reference to FIG. 5, for instance, a laminated insulating substrate (105) comprising a 1-μm biaxial stretched polyethylene terephthalate film as a first substrate (106) and a 38-μm adhesive-lined biaxial stretched polyethylene terephthalate film, made up of a biaxial stretched polyethylene terephthalate film (107a) and a 30-μm adhesive layer (107b), as a second substrate (107) may be used as an insulating substrate (100). Even when a laminated insulating substrate (105) is used as an insulating substrate (100), it is possible to obtain a wiring pattern formed on a 1-μm biaxial stretched polyethylene terephthalate film with an electroconductive pattern (301) by peeling the adhesive-lined biaxial stretched polyethylene terephthalate film (107) after the first to third steps have been completed.

Although there are no specific limitations on the thickness of the insulating substrate (100), it is preferable that it is 10 μm to 5 mm. If the thickness is less than 10 μm, the insulating substrate is susceptible to cracking, creasing or rupturing, sometimes making the substrate difficult to handle. If, on the other hand, the thickness exceeds 5 mm, the total light transmittance decreases, sometimes causing the flash light in the visible band (401) to attenuate before reaching the first surface (101) of the insulating substrate (100) on its way past the second surface (102) thereof and fail to dissolve part of the resist layer (200). If the thickness of the insulating substrate (100) is 10 μm to 5 mm as preferred, handling is easy with no risk of total light transmittance decreasing.

It suffices that the resist layer (200) contains a material that dissolves, namely at least partially evaporates, when exposed to flash light in the visible band (401) irradiated through the first surface (101) of the insulating substrate (100) via its second surface (102). Specifically, if such a resist layer (200) is irradiated with flash light in the visible band (401), its temperature momentarily reaches 400° C. or more, causing part of the resist layer (200) to evaporate. This, in turn, peels the resist layer (200) and such a part of the overlaid electroconductive thin film layer as to be removed (302) from the first surface (101) of the insulating substrate (100) and leaves such a part of the electroconductive thin film layer (300) to make up the wiring pattern (301) on the insulating substrate (100), with a wiring pattern obtained in the process.

Examples of a material for the resist layer (200) that at least partially evaporates when irradiated with flash light in the visible band (401) include any carbon (C)-containing material that evaporates if irradiated with flash light in the visible band (401) as a result of being oxidized through a reaction as described in Formula (1).

C+O₂→CO₂(gas) (1)

There are no specific limitations on the molecular type of carbon, and examples include graphite, fullerene, diamond, carbon fiber, carbon nanotube, glassy carbon, activated carbon, and carbon black.

Although there are no specific limitations on the particle size of carbon, the larger the surface area of the carbon particles contained in the resist layer (200), the more easily the energy carried by the flash light in the visible band (401) irradiated from a flash lamp (400) brings about the reaction described in Formula (1). For this reason, it suffices to select an appropriate molecular type of carbon and carbon content according to the application. When graphite is adopted, for instance, it is preferable that it contain particles 100 nm or less in primary particle diameter by at least 5 mass % or more, more preferably 10 mass % or more and even more preferably 15 mass % or more.

A resist layer (200) containing carbon may be obtained by, for instance, applying a liquid mixture of carbon, a binder resin and organic solvent via coating or printing using a generally known method. Although there are no specific limitations on carbon content, it is preferable that it is 1 to 99 parts by mass, more preferably 3 to 90 parts by mass, when the resist layer (200) measures 100 parts by mass. If carbon content is smaller than 1 part by mass, the irradiation of flash light in the visible band (401) sometimes fails to peel the resist layer (200) and such a part of the overlaid electroconductive thin film layer (300) to be removed (302) from the first surface (101) of the insulating substrate (100) even if the carbon contained in the resist layer (200) evaporates and turns into carbon dioxide gas through the reaction described in Formula (1), making it impossible to obtain the desired wiring pattern. If, on the other hand, it is greater than 99 parts by mass, the contact between the insulating substrate (100) and the resist layer (200) is poor due to small binder resin content, leading to potential problems in the second and subsequent steps. If the carbon content is 1 to 99 parts by mass as preferred, it is possible to obtain the desired wiring pattern as it ensures that the resist layer (200) and such a part of the overlaid electroconductive thin film layer (300) to be removed (302) is peeled from the first surface (101) of the insulating substrate (100) as a result of evaporation of the carbon contained in the resist layer (200) and its transformation into carbon dioxide gas through the reaction described in Formula (1) upon exposure to flash light in the visible band (401), while avoiding degradation of the contact between the insulating substrate (100) and the resist layer (200).

As an alternative way of forming a resist layer (200), a resist layer material that at least contains carbon may be processed into a uniform resist layer using a generally known method such as sputtering or vapor deposition. In this case, even if the carbon content of the resist layer (200) measuring 100 parts by mass is 100 parts by mass, the contact between the insulating substrate (100) and the resist layer (200) does not degrade, making it possible to avoid potential problems in the second and subsequent steps.

To obtain the desired wiring pattern, the so-called “laser ablation” method may then be employed to remove such a part of the resist layer (200) as to cover the wiring section (103) using a laser beam (501) emitted by a laser emission device (500).

In the first step, a resist layer (200) consisting of graphite and a binder resin may be formed through the printing of the negative wiring pattern with a liquid mixture of carbon, a binder resin and organic solvent via a method that includes at least one selected from a group of methods comprising gravure printing, flexographic printing, screen printing, offset printing, ink jet printing and photolithography, followed by drying.

Examples of the alternative ingredient of a resist layer (200) that at least partially evaporates when irradiated with flash light in the visible band (401) include toluene, xylene, methyl ethyl ketone, methyl isobutyl ketone, ethanol, methanol, isopropyl alcohol, ethyl acetate, butyl acetate and other organic solvents.

Although there are no specific limitations on the type of organic solvent, it is preferable that the boiling point is 40 to 200° C., more preferably 80 to 150° C. If the boiling point of the organic solvent is lower than 40° C., the organic solvent contained in the resist layer (200) is sometimes gradually released into the atmosphere during the phase prior to irradiation with flash light in the visible band (401). If, on the other hand, the boiling point of the organic solvent is higher than 200° C., it is necessary to increase the irradiation intensity of flash light in the visible band (401) to excessive levels, sometimes giving rise to the damage of the insulating substrate (100). If the boiling point of the organic solvent is 40 to 200° C. as preferred, it is possible to prevent the organic solvent contained in the resist layer (200) from being gradually released into the atmosphere during the phase prior to irradiation with flash light in the visible band (401), while eliminating the need to increase the irradiation intensity of flash light in the visible band (401) to excessive levels, thus avoiding the risk of damage to the insulating substrate (100).

Examples of a method to have the resist layer (200) contain an organic solvent include one in which a solution of a binder resin such as a vulcanized rubber, polyester or polyacrylic acid copolymer, is prepared by dissolving it in the organic solvent to a desired viscosity, applied using a generally known method of pattern printing such as gravure printing, flexographic printing, screen printing, offset printing or ink jet printing, and dried. The same goal can also be achieved using another method in which silica or other porous particles with an average particle diameter of some 0.01 to 10 μm that contain an organic solvent in the so-called “capsule form” as a result of being thoroughly immersed in the organic solvent are mixed with a binder resin and the above organic solvent to prepare a solution, which is then adjusted to a desired viscosity, applied in a negative wiring pattern using a generally known coating method, and dried.

Examples of such porous particles include porous silica. Although there are no specific limitations on the average pore size of porous silica, it is preferable that it is 1 to 10 nm, more preferably 2 to 5 nm, with the specific surface area of porous silica preferably 400 to 1500 m²/g, more preferably 600 to 1200 m²/g. If porous silica has an average pore size of 1 to 10 nm and/or a specific surface area of 400 to 1500 m²/g, particles are capable of sufficiently containing an organic solvent.

Although there are no specific limitations on the organic solvent content of the resist layer (200), it is preferable that it is 0.01 to 10 mass %, more preferably 0.05 to 5 mass % and even more preferably 0.1 to 3 mass %.

If the organic solvent content is less than 0.01 mass %, irradiation of flash light in the visible band (401) sometimes fails to peel the resist layer (200) and such a part of the overlaid electroconductive thin film layer (300) to be removed (302) from the first surface (101) of the insulating substrate (100) even if the organic solvent contained in the resist layer (200) evaporates, leads to an inability to obtain the desired wiring pattern. If, on the other hand, the organic solvent content is greater than 10 mass %, significant damage to the insulating substrate (100), reduction of the contact between the resist layer (200) and the insulating substrate (100), and the like sometimes occur.

If the organic solvent content is 0.01 to 10 mass %, it is possible to peel the resist layer (200) and such a part of the overlaid electroconductive thin film layer (300) to be removed (302) from the first surface (101) of the insulating substrate (100) by evaporating the organic solvent contained in the resist layer (200) through irradiation with flash light in the visible band (401) with no real damage to the insulating substrate (100), while fully maintaining the contact between the resist layer (200) and the insulating substrate (100).

Although there are no specific limitations on the thickness of the resist layer (200), it is preferable that it is 1 nm to 20 μm, more preferably 10 nm to 15 μm. If the thickness is less than 1 nm, pinholes are sometimes generated in the resist layer (200) itself, leading to the deposition of the electroconductive thin film layer (300) on unintended parts of the electroconductive substrate (100) during the second step, whose purpose is to deposit the electroconductive thin film layer (300) on the resist layer (200), as a result of leakage through those pinholes. If, on the other hand, the thickness is greater than 20 μm, it is sometimes difficult to draw a fine negative wiring pattern. If the thickness of the resist layer (200) is 10 nm to 20 μm as preferred, it is possible to draw a fine negative wiring pattern without allowing pinholes to be generated in the resist itself.

It suffices that the electroconductive thin film layer (300) is made of an electroconductive material not easily damaged if irradiated with flash light in the visible band (401). Specific examples include a metal, alloy, electroconductive polymer and other common non-carbon-based electroconductive materials.

If a carbon-based electroconductive material is used for the electroconductive thin film layer (300), irradiation of flash light in the visible band (401) sometimes evaporates and dissolves the electroconductive thin film layer (300) of a carbon-based electroconductive material, as well as the resist layer (200). Of all electroconductive materials, metal is preferable. Our methods are particularly effective when an electroconductive circuit is formed from gold, platinum, palladium or some other difficult-to-etch electroconductive material or a transparent electroconductive polymer.

Although there are no specific limitations on the thickness of the electroconductive thin film layer (300), it is preferable that it is 1 nm to 20 μm, more preferably 10 nm to 12 μm. If the thickness of the electroconductive thin film layer (300) is less than 1 nm, the resistance of the electroconductive circuit sometimes becomes too large. If, on the other hand, it is greater than 20 μm, the irradiation of flash light in the visible band (401) to dissolve the resist layer (200) sometimes fails to remove such a part of the electroconductive thin film layer (300) to be removed (302) and leaves it joined to such a part of the electroconductive thin film layer (300) to make up the wiring pattern (301), either kept in place or peeled off with it. If the thickness of the electroconductive thin film layer (300) is 1 nm to 20 μm as preferred, it is possible to obtain the desired wiring pattern as it keeps the resistance of the electroconductive circuit from becoming too large, while ensuring that the irradiation of flash light in the visible band (401) to dissolve the resist layer (200) removes such a part of the electroconductive thin film layer (300) to be removed (302) without leaving it joined to such a part of the electroconductive thin film layer (300) to make up the wiring pattern (301), either kept in place or peeled off with it.

The electroconductive thin film layer (300) may be deposited using the sputtering method and/or vapor deposition method.

Examples of the vapor deposition method include the physical vapor deposition (PVD) method, plasma-assisted chemical vapor deposition (PACVD) method, chemical vapor deposition (CVD) method, electron beam physical vapor deposition (EBPVD) method and/or metal organic chemical vapor deposition (MOCVD) method, although the list is not limited thereto. Those techniques are widely known and available for use when selectively forming a uniform thin layer made of a metal or some other electroconductive material on an insulating substrate (100).

It is preferable that the flash lamp (400) be a xenon flash lamp.

A xenon flash lamp features a rod-like glass tube encapsulating xenon and terminated with positive and negative electrodes, both connected to the capacitor of a power supply unit (electro-discharge tube), and trigger electrodes provided on the circumferential surface of the glass tube. Since xenon gas is an electrical insulator, no electric current normally flows inside the glass tube even if an electric charge is stored in the capacitor. However, if a high voltage is applied across the trigger electrodes to break the insulation, the electricity stored in the capacitor instantaneously flows through the glass tube as a result of an electrical discharge across the two terminal electrodes, with flash light with a wide spectrum in the visible band of 200 nm to 800 nm emitted in the process as a result of the excitation of xenon atoms and molecules. FIG. 8 shows an example of the spectrum of flash light irradiated from a xenon flash lamp. Such a xenon flash lamp is characterized in that it is capable of emitting very intense light compared to a continuously lit light source since the electrostatic energy pre-stored in a capacitor is converted to a very narrow light pulse lasting only 1 microsecond to 100 milliseconds. This makes it possible to quickly heat the resist layer (200) via the second surface (102) of the insulating substrate (100). This kind of a method is preferable as it can provide a treatment while causing very little temperature rise to the insulating substrate (100).

There are no specific limitations on the amount of energy released each time a flash light in the visible band (401) is irradiated, as long as it is sufficient to evaporate part of the resist layer (200). Specifically, it is preferable that the irradiating energy is 0.1 to 100 J/cm², more preferably 0.5 to 50 J/cm², although it is subject to variables such as the material and total light transmittance of the insulating substrate (100), the material, thickness and pattern shape (area) of the resist layer (200), the distance between the light source and the irradiated object, and the number of lamps emitting flash light in the visible band (401). If the irradiating energy is less than 0.1 J/cm², it is insufficient to evaporate part of the resist layer (200), sometimes resulting in a failure to peel it from the insulating substrate (100). If, on the other hand, it is greater than 100 J/cm², problems such as overheating of the resist layer (200) and damage to the insulating substrate (100) and electroconductive thin film layer (300) due to heating to extreme temperatures sometimes occur. If the irradiating energy is 0.1 to 100 J/cm² as preferred, it is sufficient to evaporate part of the resist layer (200).

Although there are no specific limitations on the distance between the flash lamp (400) and the second surface (102) of the insulating substrate (100), it is preferable that it is 10 to 1000 mm, more preferably 100 to 800 mm. If the distance between the flash lamp (400) and the second surface (102) of the insulating substrate (100) is less than 10 mm, problems such as the narrowing of the irradiation range of flash light in the visible band (401) and thermal damage to the second surface (102) of the insulating substrate (100) due to the propagation of the heat stored in the flash lamp (400) itself sometimes occur. If, on the other hand, it is greater than 1000 mm, irradiation with flash light in the visible band (401) sometimes fails to quickly heat the resist layer (200). If the distance between the flash lamp (400) and the second surface (102) of the insulating substrate (100) is 10 to 1000 mm, it is possible to quickly heat the resist layer (200) without causing thermal damage to the second surface (102) of the insulating substrate (100).

Flash light in the visible band (401) is emitted one or more times to irradiate the same region. Normally, it suffices to evaporate part of the resist layer (200) with a single irradiation. When a fine or complicated wiring pattern is involved, the desired wiring pattern can be obtained by lowering the irradiating energy per irradiation and repeating irradiation multiple times.

When emitting flash light in the visible band (401) multiple times to irradiate the same region, it is preferable that the irradiation frequency is 100 Hz or less, more preferably 1 to 50 Hz.

It is preferable that the total irradiation time of flash light in the visible band (401) targeted at the same region is 10 microseconds to 50 milliseconds, more preferably 50 microseconds to 20 milliseconds and even more preferably 100 microseconds to 5 milliseconds. If it is shorter than 10 microseconds, it is insufficient to evaporate part of the resist layer (200), sometimes resulting in a failure to peel it from the insulating substrate (100). If, on the other hand, it is longer than 50 milliseconds, problems such as overheating of the resist layer (200) and damage to the insulating substrate (100) and electroconductive thin film layer (300) due to heating to extreme temperatures sometimes occur. If the irradiation time of flash light in the visible band (401) is 10 microseconds to 50 milliseconds as preferred, it is sufficient to evaporate part of the resist layer (200), while avoiding damage to the insulating substrate (100) or electroconductive thin film layer (300) due to heating to extreme temperatures.

In the third step, the irradiation of flash light in the visible band (401) sometimes leaves residue of the evaporated and peeled resist layer (200). In that event, it suffices to remove it using a generally known method, such as suction (or some other pneumatic method) and a sticky roller.

Wiring patterns formed by our methods may advantageously be used in flexible printed wiring boards, in particular wiring boards based on difficult-to-etch noble metals such as Au, Pt and Pd.

Wiring patterns formed by our methods may be used as electrodes in biosensor chips. The wiring pattern forming method of the present invention has an environmentally advantageous effect since it allows biosensor chips to be produced, unlike prior art, without the use of a resist or etching liquid. Even when a noble metal, such as palladium, gold or platinum, is used in electrodes, biosensor chips can be produced inexpensively without the use of bloated production apparatus since, unlike prior art, laser equipment is not required.

### EXAMPLES

Our wiring pattern forming methods are now described in detail using concrete examples.

### Example 1

### (1) First Step

As an insulating substrate (100), 50-μm “Lumirror” (registered trademark) polyethylene terephthalate (PET) film with a total light transmittance (JIS K7105 (2008)) of 93% (type U34) (manufactured by Toray Industries, Inc.) was furnished.

With a graphene-based carbon plate as the target material, a 10 nm-thick uniform carbon film was then produced on the first surface (101) using DC magnetron sputtering equipment.

Next, a resist layer (200) featuring a negative wiring pattern was obtained by removing such a part of the carbon film laid over the wiring section (103) of the insulating substrate (100) line by line using the laser ablation method, wherein the carbon thin film was irradiated with a laser beam (501) from a YAG laser emission device (500) to draw ten 10 μm-wide 10 mm-long parallel lines at 20 μm intervals.

### (2) Second Step

With Pd as the target material, an electroconductive thin film layer (300) made of 20 nm-thick Pd thin film was deposited on the first surface (101) of the insulating substrate (100) obtained in the first step using the DC magnetron sputtering method.

### (3) Third Step

Using Sinteron 2000 xenon pulse irradiation equipment (manufactured by Xenon Corporation), the second surface (102) of the insulating substrate (100) obtained in the second step was irradiated with flash light in the visible band (401) for 500 microseconds once, with the carbon-film resist layer (200) dissolved in the process as a result of receiving 3.7 J/cm² of irradiating energy.

Through steps (1) to (3), it was possible to obtain a wiring pattern whose wiring section (300) was made of Pd. The formed wiring pattern was found to feature ten Pd-based 20 nm-thick 10 μm-wide 10 mm-long electroconductive lines drawn at 20 μm intervals on the first surface (101) of the insulating substrate (100) without any loss of an electroconductive line or short-circuiting between adjacent electroconductive lines.

### Example 2

### (1) First Step

A laminated insulating substrate (105) was prepared by furnishing 12.5-μm “Kapton” (registered trademark) polyimide (PI) film (type 25H) (manufactured by Du Pont-Toray Co., Ltd.) as a first substrate (106) that constituted part of the laminated insulating substrate and 59-μm “E-MASK” (registered trademark) adhesive-lined polyester film (type RP301) (manufactured by Nitto Denko Corporation) as a second substrate (107) that also constituted part of the laminated insulating substrate (105) and gluing them together. In this case, the total light transmittance was 28%.

A resist-making coat was then prepared by mixing and thoroughly stirring 15 parts by mass of porous silica (SUNSPHERE H-31: manufactured by AGC Si-Tech. Co., Ltd., average particle diameter 3 μm, specific surface area 800 m²/g, and pore diameter 5 nm), 15 parts by mass of a binder resin (“Vylon” (registered trademark) GK-250: manufactured by Toyobo Co., Ltd., amorphous polyester resin), 35 parts by mass of methyl ethyl ketone, and 35 parts by mass of toluene.

Next, a resist layer (200) featuring a 5 μm-thick negative wiring pattern was formed by printing the reversed pattern of wiring containing 80 μm-wide 30 mm-long lines drawn at 100 μm intervals on the PI film-side of the laminated insulating substrate (106) via the gravure printing method and drying it at 120° C. for 60 seconds. This material was subjected to gas chromatography headspace analysis to measure the total content of methyl ethyl ketone and toluene in the resist layer. The result was 0.6 mass %.

### (2) Second Step

With Pt as the target material, an electroconductive thin film layer (300) made of 80 nm-thick Pt thin film was deposited on the first surface (101) of the laminated insulating substrate (105) obtained in the first step using the sputtering method.

### (3) Third Step

Using Sinteron 8000 xenon pulse irradiation equipment (manufactured by Xenon Corporation), the second surface (102) of the laminated insulating substrate (105) obtained in the second step was irradiated with flash light in the visible band for 1000 microseconds six times at 1.8 Hz, with the resist layer (200) dissolved in the process as a result of receiving 75 J/cm² of irradiating energy.

Next, the second substrate (107) that constituted part of the laminated insulating substrate (105) was peeled, and this yielded a 12.5 μm-thick PI film featuring a wiring pattern that contained 80 μm-wide 30 mm-long lines drawn at 100 μm intervals.

The above wiring pattern forming method made it possible to obtain a formed wiring pattern.

### Example 3

### (1) First Step

As an insulating substrate (100), 188-nm “Lumirror” (registered trademark) polyethylene terephthalate (PET) film with a total light transmittance (JIS K7105 (2008)) of 81% (type S10) (manufactured by Toray Industries, Inc.) was furnished.

A resist-making coat was then prepared by mixing and thoroughly stirring 12.6 parts by mass of a vinyl chloride-vinyl acetate copolymer (manufactured by Dainichiseika Colour & Chemicals Mfg. Co., Ltd. NB500), 11.4 parts by mass of carbon black (“TOKABLACK” (registered trademark) #7400, manufactured by Tokai Carbon Co., Ltd.), 38 parts by mass of cyclohexanone, and 19 parts by mass of ethyl acetate.

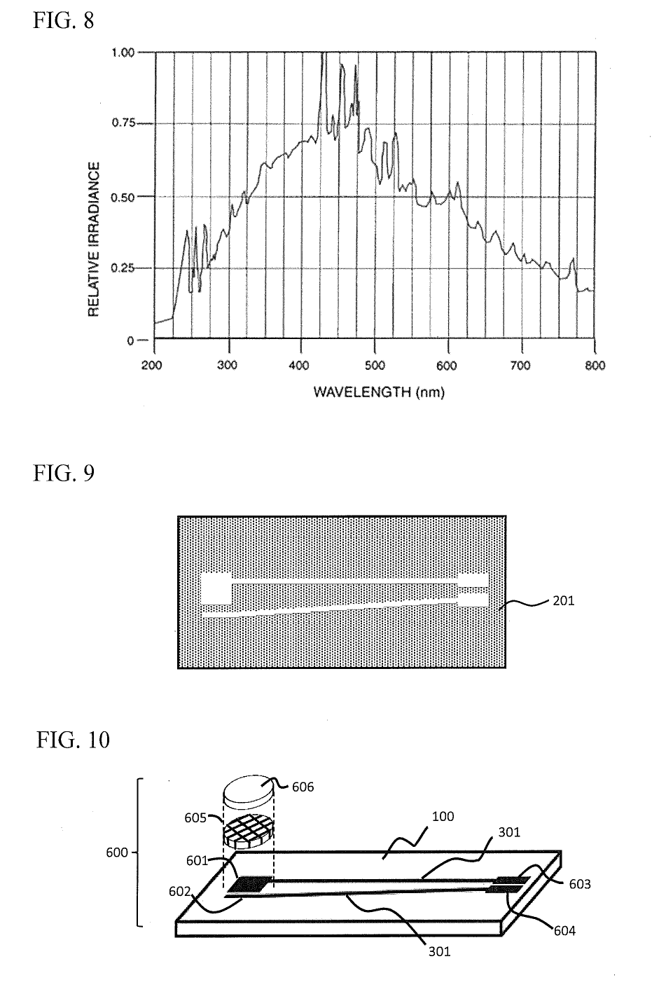

Next, a resist layer (200) featuring a 8 μm-thick negative wiring pattern was formed by printing the reversed pattern of electroconductive wiring as shown in FIG. 9 on the first surface (101) of the laminated insulating substrate (100) via the screen printing method and drying it at 150° C. for 120 seconds. This material was subjected to gas chromatography headspace analysis to measure the total content of cyclohexanone and ethyl acetate in the resist layer. The result was 1.1 mass %.

### (2) Second Step

With Au as the target material, an electroconductive thin film layer (300) made of 50 nm-thick Au thin film was deposited on the first surface (101) of the insulating substrate (100) obtained in the first step using the DC magnetron sputtering method.

### (3) Third Step

Using PulseForge 1200 xenon pulse irradiation equipment (manufactured by NovaCentrix), the second surface (102) of the insulating substrate (100) obtained in the second step was irradiated with flash light in the visible band (401) for 500 microseconds five times consecutively at 1000-microsecond intervals, with the resist layer made of film containing carbon black (200) dissolved as a result of receiving 6.7 J/cm² of irradiating energy and an Au-based enzyme battery electrode circuit produced in the process.

### (4) Production of Enzyme Battery

An electronic mediator (potassium ferricyanide) layer (605) was formed to cover both the active pole (601) and return pole (602), with an enzyme layer made of glucose oxidase (GOD) (606) deposited on top of it. An enzyme battery (600) was then produced by connecting an ammeter across the two electrodes (603) and (604) opposite the active pole (601) and return pole (602). Next, when a droplet of a 200 mM aqueous solution of glucose heated to 37° C. was placed on the enzyme layer (606), the flow of an electric current of 1.8 mA was confirmed.

### Example 4

### (1) First Step

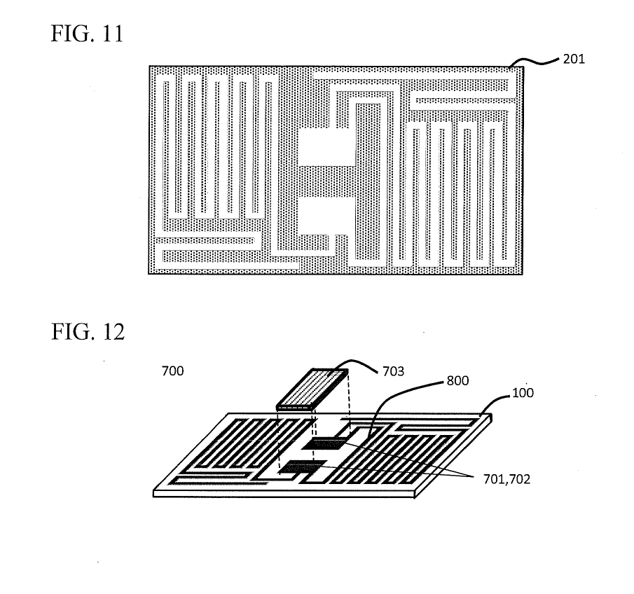

A resist layer (200) featuring a 8 μm-thick negative wiring pattern was formed by printing the reversed pattern of electroconductive wiring as shown in FIG. 11 on the first surface (101) of the laminated insulating substrate (100) via the screen printing method in the same manner as Example 3 and drying it at 150° C. for 120 seconds. This material was subjected to gas chromatography headspace analysis to measure the total content of cyclohexanone and ethyl acetate in the resist layer. The result was 2.5 mass %.

### (2) Second Step

With Al as the target material, an electroconductive thin film layer (300) made of 1.1 μm-thick Al thin film was deposited on the first surface (101) of the insulating substrate (100) obtained in the first step using the vapor deposition method.

### (3) Third Step

Using PulseForge 1200 xenon pulse irradiation equipment (manufactured by NovaCentrix), the second surface (102) of the insulating substrate (100) obtained in the second step was irradiated with flash light in the visible band (401) for 250 microseconds 10 times consecutively at 500-microsecond intervals, with the resist layer made of film containing carbon black (200) dissolved as a result of receiving 7.9 J/cm² of irradiating energy and an Al-based RFID antenna circuit (700) produced in the process.

### (4) Preparation of RFID

Next, the electrodes of a strap (interposer) mounted with a “Higgs” EPC Gen 2-compliant IC chip manufactured by Alien Technology LLC. were connected to the terminals (701, 702) of the RFID antenna circuit (700) via electroconductive paste to complete an RFID tag.

The obtained RFID tag was tested for communications characteristics using a reader-writer (Model: V750-BA50C04-JP) manufactured by Omron Corporation and an antenna (Model: V750-HS01CA-JP) manufactured by Omron Corporation. We confirmed that the RFID tag was capable of performing communications tasks.

The wiring pattern forming methods implemented under Example 1 to 4 were found to be excellent in terms of environmental and economic performance as they did not use organic solvents or acid/alkali solutions as common features of an etching step or resist-making step and thus eliminated the need for residue treatment.

As illustrated in Example 3, it was also possible to produce electrodes and other electronic circuitry made of noble metal as oxidation-resistant electroconductive material for use in an enzyme battery, glucose sensor, or the like without using expensive laser irradiation equipment, etc.

Although only a few examples that incorporate the principles of our methods have been disclosed above, these are strictly for illustrative purposes only, and this disclosure is not limited thereto. Namely, the applicability of our methods extends to all variations, purposes of use and adaptations thereof, which involve the above general principles. The applicability of our methods is, to such an extent as to be limited by the appended claims, also deemed to reach techniques that deviate from the disclosure, as long as they belong to technical fields to which our methods relate and lie within the known or conventional technical range.

### INDUSTRIAL APPLICABILITY

Wiring patterns formed through the use of the wiring pattern forming method are applicable to the production of electroconductive circuits.

1-14. (canceled)

15. A wiring pattern forming method comprising a first, second, and third step performed in sequence, the first step comprising depositing a resist layer on the non-wiring section of the first surface of an insulating substrate,
the second step comprising depositing an electroconductive thin film layer on the wiring section and at least part of the resist layer, and
the third step comprising radiating flash light in the visible band from a flash lamp onto at least the second surface of the resist layer via the second surface of the insulating substrate and dissolving the resist layer to form a wiring pattern made of the electroconductive thin film layer in the wiring section.

16. The method as described in claim 15, wherein total light transmittance of the insulating substrate is 20% or more.

17. The method as described in claim 15, wherein the resist layer contains carbon.

18. The method as described in claim 15, wherein the resist layer contains an organic solvent.

19. The method as described in claim 18, wherein the boiling point of the organic solvent is 200° C. or less.

20. The method as described in claim 15, wherein the resist layer is formed by at least one selected from a group of methods consisting of gravure printing, flexographic printing, screen printing, offset printing, ink jet printing and photolithography.

21. The method as described in claim 15, wherein, after the resist layer is formed, a part thereof covering the wiring section is removed using the laser ablation method.

22. The method as described in claim 15, wherein the electroconductive thin film layer is made of an electroconductive material that is not carbon-based.

23. The method as described in claim 15, wherein thickness of the electroconductive thin film layer is 1 nm to 20 μm.

24. The method as described in claim 15, wherein the electroconductive thin film layer is deposited using the sputtering method and/or vapor deposition method.

25. The method as described in claim 15, wherein the irradiation of flash light in the visible band causes at least part of the resist layer to evaporate.

26. The method as described in claim 15, wherein irradiation energy of flash light in the visible band is 0.1 to 100 J/cm².

27. A wiring pattern formed by the method described in claim 15.

28. A biosensor chip incorporating a wiring pattern as described in claim 27.

29. The method as described in claim 16, wherein the resist layer contains carbon.

30. The method as described in claim 16, wherein the resist layer contains an organic solvent.

31. The method as described in claim 17, wherein the resist layer contains an organic solvent.

32. The method as described in claim 16, wherein the resist layer is formed by at least one selected from a group of methods consisting of gravure printing, flexographic printing, screen printing, offset printing, ink jet printing and photolithography.

33. The method as described in claim 17, wherein the resist layer is formed by at least one selected from a group of methods consisting of gravure printing, flexographic printing, screen printing, offset printing, ink jet printing and photolithography.

34. The method as described in claim 18, wherein the resist layer is formed by at least one selected from a group of methods consisting of gravure printing, flexographic printing, screen printing, offset printing, ink jet printing and photolithography.
